(19) United States
(12) Patent Application Publication
(10) Pub. No.: US 2023/0195973 A1
(43) Pub. Date: Jun. 22, 2023

(54) COMPUTER SIMULATION OF CROPS BASED ON AGRICULTURE INFLUENCING FACTORS

(71) Applicant: International Business Machines Corporation, Armonk, NY (US)

(72) Inventors: Raghuveer Prasad Nagar, Kota (IN); Sarbajit K. Rakshit, Kolkata (IN); Subba Rayudu Tangirala, Bangalore (IN)

(21) Appl. No.: 17/645,168

(22) Filed: Dec. 20, 2021

(51) Int. Cl. G06F 30/27; G06N 5/04

(52) U.S. Cl. CPC G06F 30/27; G06N 5/04

(57) ABSTRACT

Computer technology that delivers simulation of crop growth, with the simulation accounting for various “influencing factors.” Artificial intelligence type software makes various recommendations to the farmers growing the agricultural crops. Some embodiments are directed to forestry and/or livestock instead of crops. Some embodiments include simulation of damaging natural forces within computer simulations of forestry and/or agriculture.

### BACKGROUND

The present invention relates generally to the field of computer simulation, and more particularly to applying computer simulation to agriculture.

The Wikipedia entry for “Computer Simulation” (as of Aug. 17, 2021) states, in part, as follows: “Computer simulation is the process of mathematical modelling, performed on a computer, which is designed to predict the behaviour of, or the outcome of, a real-world or physical system. The reliability of some mathematical models can be determined by comparing their results to the real-world outcomes they aim to predict. Computer simulations have become a useful tool for the mathematical modeling of many natural systems in physics (computational physics), astrophysics, climatology, chemistry, biology and manufacturing, as well as human systems in economics, psychology, social science, health care and engineering. Simulation of a system is represented as the running of the system's model. It can be used to explore and gain new insights into new technology and to estimate the performance of systems too complex for analytical solutions. Computer simulations are realized by running computer programs that can be either small, running almost instantly on small devices, or large-scale programs that run for hours or days on network-based groups of computers. The scale of events being simulated by computer simulations has far exceeded anything possible (or perhaps even imaginable) using traditional paper-and-pencil mathematical modeling.”

The Wikipedia entry for “Agriculture” (as of Aug. 17, 2021) states, in part, as follows: “Agriculture is the practice of cultivating plants and livestock. Agriculture was the key development in the rise of sedentary human civilization, whereby farming of domesticated species created food surpluses that enabled people to live in cities . . . . Modern agronomy, plant breeding, agrochemicals such as pesticides and fertilizers, and technological developments have sharply increased crop yields . . . Environmental issues include . . . depletion of aquifers . . . ”(footnote(s) omitted)

### SUMMARY

According to an aspect of the present invention, there is a method, computer program product and/or system that performs the following operations (not necessarily in the following order): (i) receiving initial configuration data set for an agricultural crop area, with the initial configuration data set including information on location size and color(s) of the plants that make up a crop being grown in the agricultural crop area; (ii) configuring a simulator in an initial configuration based on the initial configuration data set; (iii) running the simulator starting in the initial configuration and simulating actions and/or conditions to obtain a simulated end configuration for the agricultural crop area, with the simulation including simulation of a first natural force; and (iv) performing artificial intelligence analysis on the simulated end configuration to obtain a first recommendation for improving the agricultural crop area.

According to an aspect of the present invention, there is a method, computer program product and/or system that performs the following operations (not necessarily in the following order): (i) receiving initial configuration data set for a livestock area, with the initial configuration data set including information on location size and color(s) of organisms being raised in the livestock area; (ii) configuring a simulator in an initial configuration based on the initial configuration data set; (iii) running the simulator starting in the initial configuration and simulating actions and/or conditions to obtain a simulated end configuration for the livestock area, with the simulation including simulation of a first damaging natural force; and (iv) performing artificial intelligence analysis on the simulated end configuration to obtain a first recommendation for improving the agricultural crop area.

According to an aspect of the present invention, there is a method, computer program product and/or system that performs the following operations (not necessarily in the following order): (i) receiving initial configuration data set for a forestry area, with the initial configuration data set including information on location size and color(s) of trees existing in the forestry area; (ii) configuring a simulator in an initial configuration based on the initial configuration data set; (iii) running the simulator starting in the initial configuration and simulating actions and/or conditions to obtain a simulated end configuration for the forestry area, with the simulation including simulation of a first damaging natural force; and (iv) performing artificial intelligence analysis on the simulated end configuration to obtain a first recommendation for improving the forestry area.

### BRIEF DESCRIPTION OF THE DRAWINGS

FIG. 1 is a block diagram view of a first embodiment of a system according to the present invention;

FIG. 2 is a flowchart showing a first embodiment method performed, at least in part, by the first embodiment system;

FIG. 3 is a block diagram showing a machine logic (for example, software) portion of the first embodiment system;

FIG. 4 is a screenshot view generated by the first embodiment system;

FIG. 5 is a first diagram of a second embodiment of a system according to the present invention; and

FIG. 6 is a second diagram of the second embodiment system.

### DETAILED DESCRIPTION

Some embodiments of the present invention are directed to simulation of crop growth, with the simulation accounting for various forces of nature (for example, storms, floods). In some embodiments, based on simulation, then machine logic according to the present invention will make various recommendations to the farmers growing the agricultural crops. Example recommendations: (i) “better results will be obtained by pre-mature harvesting the green tomatoes prior to a predicted bug infestation;” or (ii) “the crops can now sustain the storms that are likely to eventuate over the next few weeks.” AR/VR (augmented reality/virtual reality) hardware, such as goggles, will show this simulation considering the influencing factors, types of crops, surrounding area etc. and the farmer can take decision by looking at both her fields, seen through the goggles, and the running simulation of her fields, displayed in the goggles, at the same time. Various embodiments of the invention may simulate: (i) agricultural crops (for example, rice, mangoes, maple sap); (ii) agricultural animals (bees, salmon, goats); and/or (iii) forestry (for example, a forest controlled in its configuration by forestry workers).

Some currently conventional agricultural simulation computer systems perform image analysis-based identification of a treatment to be applied on the agricultural field. On the other hand, some embodiments of the present invention include simulation of “damaging natural forces” within computer simulations of forestry and/or agriculture. These damaging natural forces may include: fire, flood, earthquake, tsunami, nuclear radiation, sunlight, ice, snow, insects, worms, wild animals, magnetic forces, pollen, natural chemicals (for example, high pH versus low pH soil, salinity level of water) and tidal forces.

This Detailed Description section is divided into the following subsections: (i) The Hardware and Software Environment; (ii) Example Embodiment; (iii) Further Comments and/or Embodiments; and (iv) Definitions.

### I. The Hardware and Software Environment

The present invention may be a system, a method, and/or a computer program product at any possible technical detail level of integration. The computer program product may include a computer readable storage medium (or media) having computer readable program instructions thereon for causing a processor to carry out aspects of the present invention. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (for example, light pulses passing through a fiber-optic cable), or electrical signals transmitted through a wire.

A “storage device” is hereby defined to be anything made or adapted to store computer code in a manner so that the computer code can be accessed by a computer processor. A storage device typically includes a storage medium, which is the material in, or on, which the data of the computer code is stored. A single “storage device” may have: (i) multiple discrete portions that are spaced apart, or distributed (for example, a set of six solid state storage devices respectively located in six laptop computers that collectively store a single computer program); and/or (ii) may use multiple storage media (for example, a set of computer code that is partially stored in as magnetic domains in a computer's non-volatile storage and partially stored in a set of semiconductor switches in the computer's volatile memory). The term “storage medium” should be construed to cover situations where multiple different types of storage media are used.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

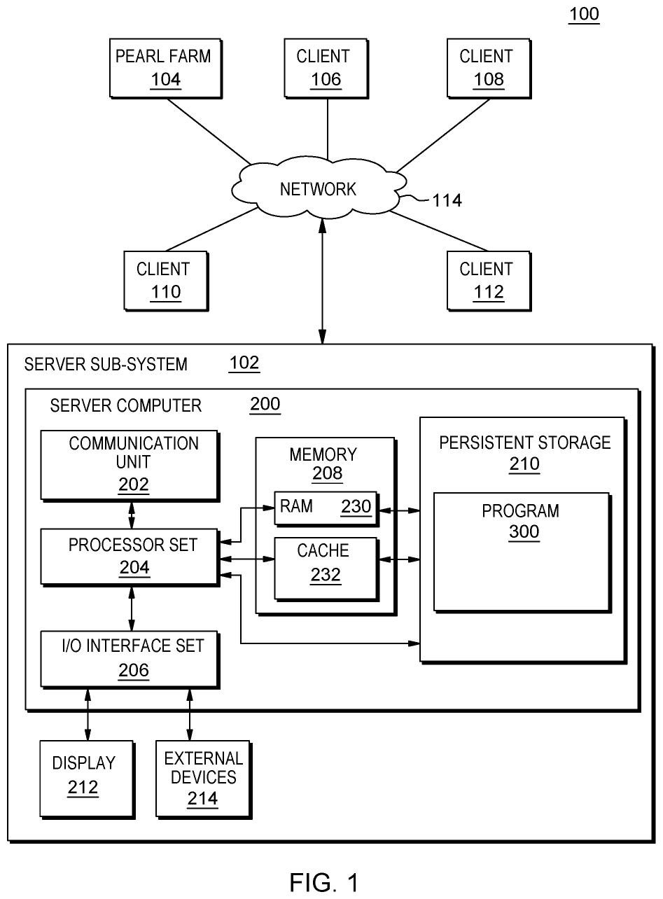

As shown in FIG. 1, networked computers system 100 is an embodiment of a hardware and software environment for use with various embodiments of the present invention. Networked computers system 100 includes: server subsystem 102 (sometimes herein referred to, more simply, as subsystem 102); pearl farm 104; client subsystems 106, 108, 110, 112; and communication network 114. Server subsystem 102 includes: server computer 200; communication unit 202; processor set 204; input/output (I/O) interface set 206; memory 208; persistent storage 210; display 212; external device(s) 214; random access memory (RAM) 230; cache 232; and program 300.

Subsystem 102 may be a laptop computer, tablet computer, netbook computer, personal computer (PC), a desktop computer, a personal digital assistant (PDA), a smart phone, or any other type of computer (see definition of “computer” in Definitions section, below). Program 300 is a collection of machine readable instructions and/or data that is used to create, manage and control certain software functions that will be discussed in detail, below, in the Example Embodiment subsection of this Detailed Description section.

Subsystem 102 is capable of communicating with other computer subsystems via communication network 114. Network 114 can be, for example, a local area network (LAN), a wide area network (WAN) such as the Internet, or a combination of the two, and can include wired, wireless, or fiber optic connections. In general, network 114 can be any combination of connections and protocols that will support communications between server and client subsystems.

Subsystem 102 is shown as a block diagram with many double arrows. These double arrows (no separate reference numerals) represent a communications fabric, which provides communications between various components of subsystem 102. This communications fabric can be implemented with any architecture designed for passing data and/or control information between processors (such as microprocessors, communications and network processors, etc.), system memory, peripheral devices, and any other hardware components within a computer system. For example, the communications fabric can be implemented, at least in part, with one or more buses.

Memory 208 and persistent storage 210 are computer-readable storage media. In general, memory 208 can include any suitable volatile or non-volatile computer-readable storage media. It is further noted that, now and/or in the near future: (i) external device(s) 214 may be able to supply, some or all, memory for subsystem 102; and/or (ii) devices external to subsystem 102 may be able to provide memory for subsystem 102. Both memory 208 and persistent storage 210: (i) store data in a manner that is less transient than a signal in transit; and (ii) store data on a tangible medium (such as magnetic or optical domains). In this embodiment, memory 208 is volatile storage, while persistent storage 210 provides nonvolatile storage. The media used by persistent storage 210 may also be removable. For example, a removable hard drive may be used for persistent storage 210. Other examples include optical and magnetic disks, thumb drives, and smart cards that are inserted into a drive for transfer onto another computer-readable storage medium that is also part of persistent storage 210.

Communications unit 202 provides for communications with other data processing systems or devices external to subsystem 102. In these examples, communications unit 202 includes one or more network interface cards. Communications unit 202 may provide communications through the use of either or both physical and wireless communications links. Any software modules discussed herein may be downloaded to a persistent storage device (such as persistent storage 210) through a communications unit (such as communications unit 202).

I/O interface set 206 allows for input and output of data with other devices that may be connected locally in data communication with server computer 200. For example, I/O interface set 206 provides a connection to external device set 214. External device set 214 will typically include devices such as a keyboard, keypad, a touch screen, and/or some other suitable input device. External device set 214 can also include portable computer-readable storage media such as, for example, thumb drives, portable optical or magnetic disks, and memory cards. Software and data used to practice embodiments of the present invention, for example, program 300, can be stored on such portable computer-readable storage media. I/O interface set 206 also connects in data communication with display 212. Display 212 is a display device that provides a mechanism to display data to a user and may be, for example, a computer monitor or a smart phone display screen.

In this embodiment, program 300 is stored in persistent storage 210 for access and/or execution by one or more computer processors of processor set 204, usually through one or more memories of memory 208. It will be understood by those of skill in the art that program 300 may be stored in a more highly distributed manner during its run time and/or when it is not running. Program 300 may include both machine readable and performable instructions and/or substantive data (that is, the type of data stored in a database). In this particular embodiment, persistent storage 210 includes a magnetic hard disk drive. To name some possible variations, persistent storage 210 may include a solid state hard drive, a semiconductor storage device, read-only memory (ROM), erasable programmable read-only memory (EPROM), flash memory, or any other computer-readable storage media that is capable of storing program instructions or digital information.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### II. Example Embodiment

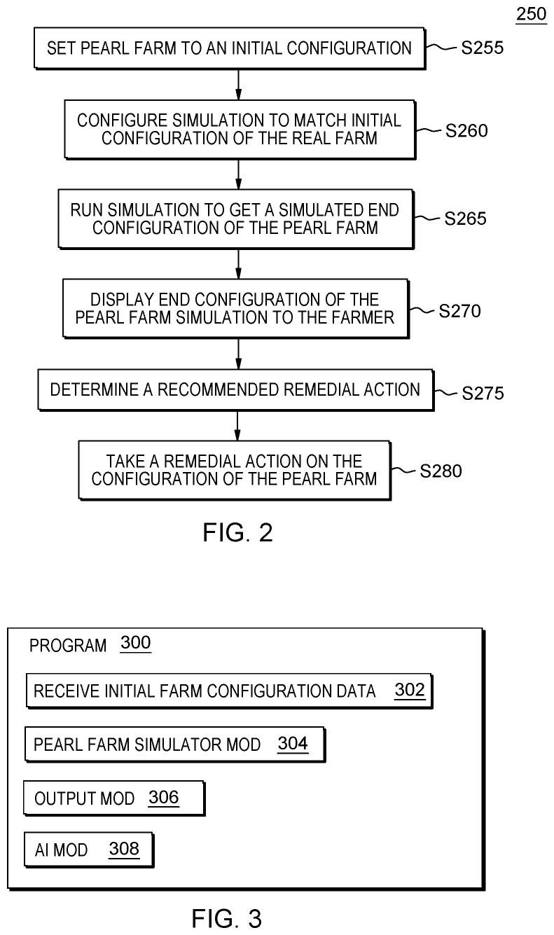

As shown in FIG. 1, networked computers system 100 is an environment in which an example method according to the present invention can be performed. As shown in FIG. 2, flowchart 250 shows an example method according to the present invention. As shown in FIG. 3, program 300 performs or controls performance of at least some of the method operations of flowchart 250. This method and associated software will now be discussed, over the course of the following paragraphs, with extensive reference to the blocks of FIGS. 1, 2 and 3.

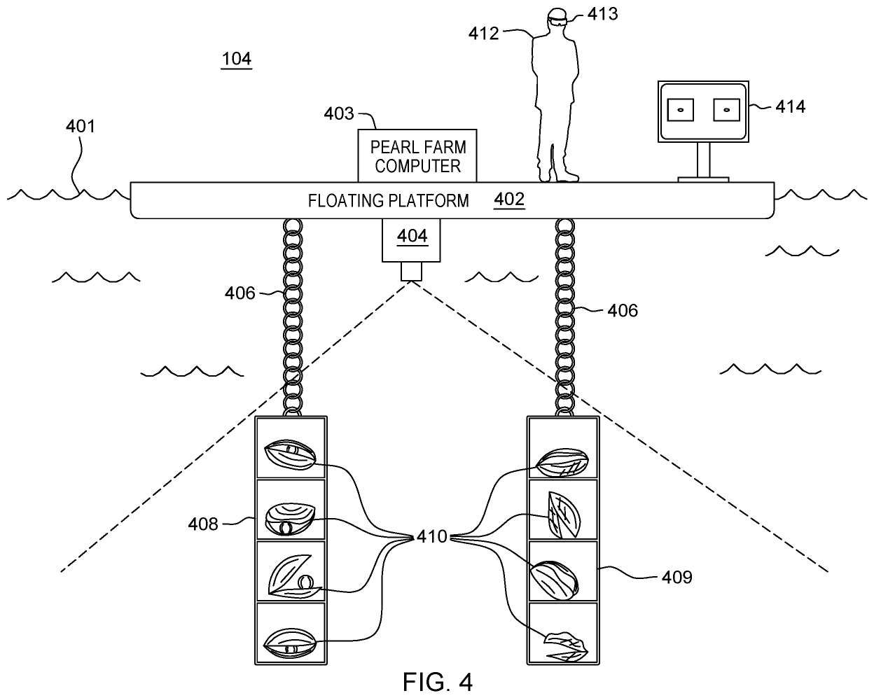

Processing begins at operation S255, where floating pearl farm 104 is set up in an initial configuration. This pearl farm is shown in FIG. 4 and includes: Diamond Sea 401, floating platform 402; pearl farm computer 403; monitoring camera 404; suspension lines 406; first oyster cage 408; second oyster cage 409; livestock 410 (also, more specifically referred to as oysters 410); farmer 412; augmented reality (AR) goggles 413; and pearl farm monitor display 414. In this example, oysters 410 in first oyster cage 408 are in good condition and repair, although the pearls are not quite ready or ripe. In this example, oysters 410 in second oyster cage 409 are in some disarray and are not growing well due to repeated bumping by a large shark (not shown). While farmer 412 has some visibility of the oysters due to monitoring camera 404 and its display shown on pearl farm monitor display 414, the farmer can't really see enough to determine the well-placed oysters (cage 408) from those in disarray (cage 409). This is compounded by the fact that none of the oysters is fully grown yet. This current status of the farm, with its eight baby oysters, is its initial real world configuration—FIG. 4 shows the pearl farm as it really exists in the real world at a starting time called T0. This “real world” description is noted because, in subsequent operations of the method of flowchart 250, there will be a simulated pearl farm as well.

Processing proceeds to operation S260, where receive initial configuration module (mod) 302 of program 300, receives initial configuration data set for the livestock area represented by pearl farm 104. This initial configuration data is collected by monitoring camera 404 and sent to server subsystem 102 through pearl farm computer 403 and network 114. Some other information is also sent to reflect the initial configuration, such as the salinity of the local waters of Diamond Sea 401. While this example is drawn to a livestock area, alternatively: (i) the area could be an agricultural area with a crop; and/or (ii) a forestry area with forestry resources, such as trees. Note the initial configuration data set sent to mod 302 includes information on the number and size of the oysters. In plant based embodiments, color information about the plants of the crop, or forest, will also typically be sent. At operation S260, the initial configuration data set is used to configure pearl farm simulator mod 304 so that the simulation will match what is likely to happen at the real pearl farm as closely as possible.

Processing proceeds to operation S265, where simulator mod 304 begins running a simulation that starts in the initial configuration and simulates the progress of the livestock (or plants) as they grow and mature over simulated time. Output mod 306 sends the simulation video to farmer 412, who watches this simulation through AR goggles 413. The simulation includes simulation of damaging natural force(s). In this case, the two damaging natural forces that are modelled in the simulation are: (i) salinity changes in the water as the pearl growing season progresses; and (ii) likelihood of encountering sharks.

Processing proceeds to operation S270, where actions and/or conditions to obtain a simulated end configuration for the pearl farm. In this example: (i) the changes in salinity do not pose any problem to the growth of the oysters and their respectively associated pearls; (ii) there were moderate, but not severe, shark attacks on the cages; and (iii) the existing disarrayed status oysters 410 in second cage 409 poses a problem. In this example, towards the end of the simulation, a simulation of farmer 412 pulls up all eight oysters (now fully grown in the simulated world) and finds: (i) a pearl in each oyster pulled out of a simulation of first cage 408; and (ii) no pearl in each oyster pulled out of a simulation of second cage 409. At this point, even without recourse to artificial intelligence, it is understood that there will be some kind of remedial action involving second cage 409.

Processing proceeds to step S275, where AI mod 308 performs artificial intelligence analysis on the simulated end configuration to obtain a first recommendation for improving the value of the yield of the pearl farm. In this example, mod 308 determines that the simulated pearls from first cage 408 are smaller, and less valuable, than they could be due to further shark disruptions of first cage 408. Accordingly, AI mod 308 determines two remedial action: (i) apply shark repellant to the real world versions of both first cage 408 and second cage 409; and (ii) pull up second cage 409 in order to replace the oysters held there into their proper spatial orientations. Output mod 306 sends a text message identifying these two recommended remedial actions to pearl farm computer 403.

Processing proceeds to operation S280, where the farmer performs the remedial actions identified in the previous paragraph on the cages and their oysters.

Some embodiments may include one, or more, of the following features, characteristics, operations and/or advantages: (i) re-running the simulator with the re-running of the simulation includes performance of the first recommendation to confirm that the first recommendation is likely to work successfully; (ii) implementing the AI generated remedial recommendation(s) to the agricultural crop area/forestry area/livestock area; (iii) the agricultural crop area includes at least one of the following kinds of plants: food plants, textile material plants, pharmaceutical plants and/or industrial use plants; (iv) the first damaging natural force is of one of the following types: fire, flood, earthquake, tsunami, solar radiation, other radiation from natural sources, ice, snow, insects, worms, wild animals, magnetic forces, pollen, natural chemicals and tidal forces.

### III. Further Comments and/or Embodiments

Some embodiments of the present invention recognize the following facts, potential problems and/or potential areas for improvement with respect to the current state of the art: (i) various unknown situations are often come across where the impact of the unpredicted situations would not have been realized (for example, if there is a lightning strike on a building, then what will happen may not be realized, that's is, the building may or may not have lighting arresters); (ii) in many situations, estimating the gravity of any problem or situation may not be possible, such as the problem, the impact, etc.; (iii) if any known measurable scenario or situation can be correlated, then the gravity of the identified unknown situation can be understood; and/or (iv) what is needed is a way by which the system can help a user understand the problem and impact when the user can't estimate the gravity of any problem or unforeseen situation.

Some embodiments of the present invention may include one, or more, of the following operations, features, characteristics and/or advantages: (i) disclosed is an AI (artificial intelligence), AR (augmented reality) and IoT (internet of things) based system and method by which, if a user can't estimate the gravity of any problem related to any contextual situation; and/or (ii) the system will correlate the same with known measurable situations so that the user can understand the gravity of any problem.

Some embodiments of the present invention may include one, or more, of the following operations, features, characteristics and/or advantages: (i) considering a given visual surrounding and contextual scenario, the AI enabled system will use digital twin simulation and a virtual reality (AR) system to show various influencing factors which can create any positive or negative impact in the said visual surrounding based on the given contextual situation (for example, the user is looking at a “paddy cultivation field”); (ii) using historical learning, the system will identify various influencing parameters, such as applying pesticides, watering, sunlight, fertilizer, rainstorm, etc.; and/or (iii) using an AR device, the user can select one or more influencing factors displayed on the AR system, and accordingly, based on selected configuration values of different influencing factors, the digital twin simulation and AI enabled system will dynamically update the visual surrounding to show how the surrounding will be impacted (for example, the user can select, any one or more influencing parameters to simulate what will be the change in the contextual situation, such as the user wants to simulate the effect of rain and pesticides in a “paddy cultivation field”).

Some embodiments of the present invention may include one, or more, of the following operations, features, characteristics and/or advantages: (i) using an AR device, the user can change the degree of selected influencing parameters, and accordingly (based on the selected degree of influencing parameters), the AR system will dynamically create the contextual situation in the surrounding; (ii) the influencing factors can be auto-injected into the system and accordingly a simulated outcome will be created, and/or (iii) the digital twin and AI enabled system will simulate the surrounding and will show the same in the AR/AR system (for example, the user can change the degree of the influencing parameters, such as from drizzle to heavy rain, where the user can simulate the change in the contextual situation, such as there will be a loss in cultivation as water will accumulate).

Some embodiments of the present invention may include one, or more, of the following operations, features, characteristics and/or advantages: (i) the system will analyze IoT and visual feed of the contextual situation to identify the capabilities of the contextual situation, and accordingly, a digital twin simulation and AI system will simulate the surrounding and with the AR system, the impact of the change because of the contextual situation will be shown (for example, the capability of the cultivation field is, water will not be accumulated, proper shading is provided, etc., so based on the selected parameters and degree of selected parameters, the system will simulate the appropriate contextual situation, such as, even if heavy rain is selected, there will not be a heavy loss); (ii) the system will identify which influencing parameters will create more impact in the surrounding context and will recommend the user to simulate the contextual situation with the recommended influencing parameters; and/or (iii) the digital twin simulation will identify the most important influencing parameters (for example, as per the current situation, rain and storm will create a larger impact, so that a user can take proactive action).

Some embodiments of the present invention may include one, or more, of the following operations, features, characteristics and/or advantages: (i) the system can create a reverse simulation, where the current contextual surrounding, and the final contextual surrounding will be provided, and accordingly the system will predict what would be the influencing factors and the level of the influence (for example, the level of the storm, rain can cause a given scenario); and/or (ii) using a historical knowledge corpus, the system will provide the appropriate recommendation to be performed by predicting the situation in which the visible items/components will be used, so that the user can reduce the damage because of the predicted types and the level of influencing factors (for example, if crop X and Y are options, but heavy rains are predicted in the next few weeks, the system will recommend crop X if it has less/no impact due to rain (when compared with crop Y).

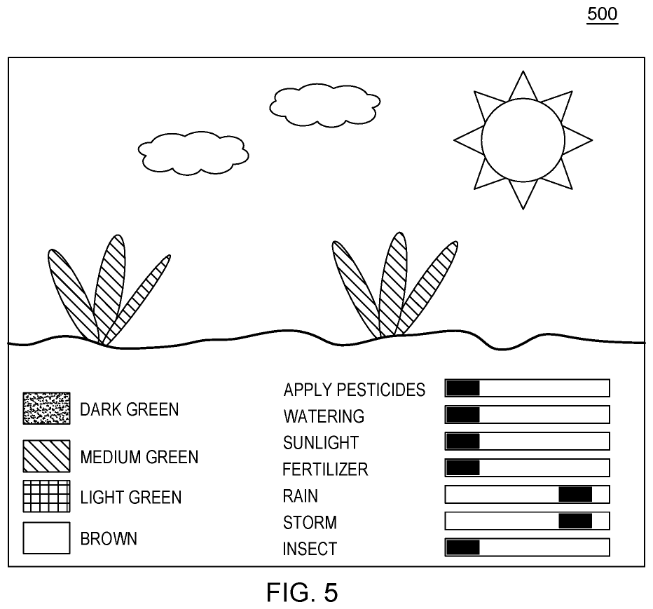

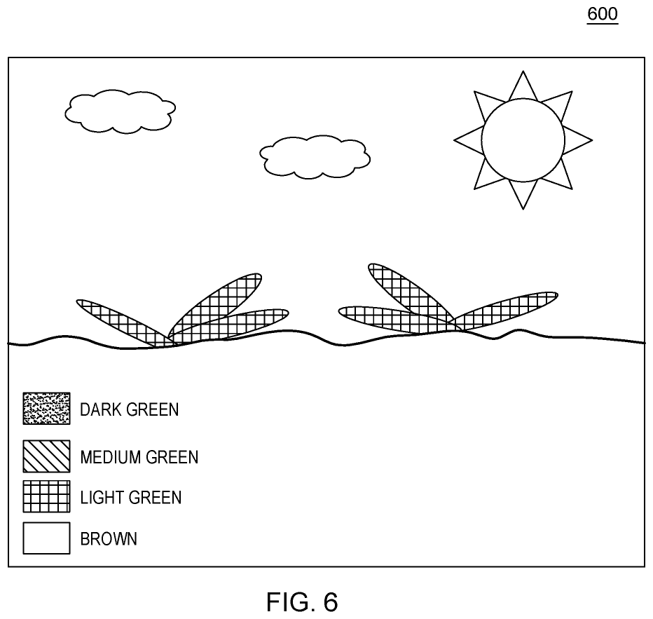

As shown in FIG. 5, diagram 500, and FIG. 6, diagram 600, these two (2) diagrams show how the AR system will show influencing factors of any surrounding context and will allow the user to make a selection. Accordingly, the AR content generation engine will create a simulated AR environment to explain the impact in the surrounding. Also shown in FIGS. 5 and 6 is the legend to the health of the plant, that being Dark Green, Medium Green, Light Green, and Brown.

Further, FIG. 5 shows seven (7) different influencing factors of the identified contextual surroundings. These influencing factors are Apply Pesticides, Watering, Sunlight, Fertilizer, Rain, Storm, and Insect. As can be seen, the user changed two (2) influencing factors (the Rain and the Storm settings). Then, as shown in FIG. 6, VR is simulating what will happen in the surrounding for the selected influencing factors.

Some embodiments of the present invention may include one, or more, of the following operations, features, characteristics and/or advantages: (i) the data gathering module will gather information from various sources of different contextual situations such as news, an analysis report, research, video of image feed, IoT feed from the surrounding, manual update, etc.; (ii) various concepts, image objects, various events, etc. will be extracted from the received data, where the data gathering module will use: (a) natural language processing techniques, such as syntax and semantics analysis to understand the information in text form, (b) deep learning techniques like R-CNN (region based convolutional neural networks) to understand the information in image/video form, and/or (c) cognitive tools to perform a real-time internet search; and/or (iii) in this case the extracted information for any “paddy cultivation field” situation can be: (a) what types of activities are performed, such as watering, applying fertilizer, etc.; (b) what are the environmental parameters such as weather, (c) changes in the surrounding context in a time scale such as damage, and/or (d) detail about the identified contextual situation, such as dimension of the “paddy cultivation field”, in the IoT controlled watering, water management system, etc.

Some embodiments of the present invention may include one, or more, of the following operations, features, characteristics and/or advantages: (i) based on the historical information, the system will identify the influencing parameters, such as which parameters are associated to the contextual surrounding that is creating the impact; (ii) the said parameters will identify uniquely, and the system will consider those parameters as influencing parameters; (iii) using historical data, the system will identify various degrees of influencing parameters, such as low to high and the range; (iv) the digital twin simulation model will create, based on a historically created knowledge corpus and will be used for digital simulating of the surrounding; and/or (v) the system will identify the impact of the influencing parameters, such as damage, growing better, etc.

Some embodiments of the present invention may include one, or more, of the following operations, features, characteristics and/or advantages: (i) based on the gathered data, the system will create a knowledge corpus which will correlate: (a) how different contextual situations can change based on different influencing factors, (b) degree of influencing factor with change in contextual situation, and/or (c) impact in the contextual situation based on the change in the influencing factors, etc.; (ii) when a user looks at any surrounding, the system will gather detail of the contextual situation from the context specific database, such as the database will store real-time IoT feeds, etc.; (iii) using an AR device, the user will view the physical surrounding, and can view the physical surrounding context; and/or (iv) the AR device will connect the knowledge corpus of various influencing factors.

Some embodiments of the present invention may include one, or more, of the following operations, features, characteristics and/or advantages: (i) the AR device will identify the contextual situation; (ii) the AR device will show all the possible influencing parameters which can create an impact to the identified contextual situation; (iii) the user can select one or more influencing factors from the AR interface; (iv) while selecting the influencing parameters, the user can also set the degree of influencing parameters; (v) the degree of influencing factors can be selected with a visual scrolling method; and/or (vi) the degree of influencing factors can be selected in a defined scale.

Some embodiments of the present invention may include one, or more, of the following operations, features, characteristics and/or advantages: (i) the AR content generation engine will capitate the visual surrounding; (ii) the AR content generation engine will also identify the capabilities of the contextual situation; (iii) based on the selected influencing parameters and degree of influencing parameters, the system will generate AR contents; (iv) the AR content will generate for the defined influencing factors; (v) the AR content will simulate the impact in the contextual situation; and/or (vi) the user can visualize what scenario can happen with the selected influencing parameters.

Some embodiments of the present invention may include one, or more, of the following operations, features, characteristics and/or advantages: (i) identifying the contextual situation of the surrounding and showing the influencing factors which can create any positive or negative impact on the identified context of the surrounding; (ii) includes influencing factors and allows the user to select one or more factors in order to simulate the changes because of the selected influencing parameters; (iii) simulates the changes to the content with the user input (selecting of influential parameters); and/or (iv) simulates the augmented content based on the influential factors that the user selects.

Some embodiments of the present invention may include one, or more, of the following operations, features, characteristics and/or advantages: (i) includes an AI, AR and IoT based digital twin system which identifies the surrounding contextual scenario and shows various influencing factors; (ii) allows the user to change the degree of the influencing factors, based on which, the system can simulate positive or negative impact in the surrounding contextual situation; (iii) dynamically determines the influencing factors; (iv) simulates the impact of the surrounding context based on the degree of influencing factors selection; (v) simulates the situation based on the degree of the influence factors that was selected; and/or (vi) identifies the contextual situation of the surrounding and provides the various influential parameters that can impact the situation.

Some embodiments of the present invention may include one, or more, of the following operations, features, characteristics and/or advantages: (i) identifies the influential parameters dynamically based on the contextual learning of the situation of the surroundings; and/or (ii) uses a historical knowledge corpus that was captured from various sources to identify the contextual situation and the factors that are influencing the context and virtualize the impact based on the selection of influential factors.

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above—similar cautions apply to the term “embodiment.”

And/or: inclusive or; for example, A, B “and/or” C means that at least one of A or B or C is true and applicable.

Including/include/includes: unless otherwise explicitly noted, means “including but not necessarily limited to.”

Module/Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Computer: any device with significant data processing and/or machine readable instruction reading capabilities including, but not limited to: desktop computers, mainframe computers, laptop computers, field-programmable gate array (FPGA) based devices, smart phones, personal digital assistants (PDAs), body-mounted or inserted computers, embedded device style computers, application-specific integrated circuit (ASIC) based devices.

What is claimed is:

1. A computer-implemented method (CIM) comprising:
receiving initial configuration data set for an agricultural crop area, with the initial configuration data set including information on location size and color(s) of the plants that make up a crop being grown in the agricultural crop area;
configuring a simulator in an initial configuration based on the initial configuration data set;
running the simulator starting in the initial configuration and simulating actions and/or conditions to obtain a simulated end configuration for the agricultural crop area, with the simulation including simulation of a first natural force; and
performing artificial intelligence analysis on the simulated end configuration to obtain a first recommendation for improving the agricultural crop area.

2. The CIM of claim 1 further comprising:
re-running the simulator with the re-running of the simulation includes performance of the first recommendation to confirm that the first recommendation is likely to work successfully.

3. The CIM of claim 1 further comprising:
sending the first recommendation to a device of a farmer who farms the agricultural crop area.

4. The CIM of claim 3 further comprising:
implementing the first recommendation of the agricultural crop area.

5. The CIM of claim 1 wherein the agricultural crop area includes at least one of the following kinds of plants: food plants, textile material plants, pharmaceutical plants and/or industrial use plants.

6. The CIM of claim 1 wherein the first damaging natural force is of one of the following types: fire, flood, earthquake, tsunami, solar radiation, other radiation from natural sources, ice, snow, insects, worms, wild animals, magnetic forces, pollen, natural chemicals and tidal forces.

7. A computer-implemented method (CIM) comprising:
receiving initial configuration data set for a livestock area, with the initial configuration data set including information on location size and color(s) of organisms being raised in the livestock area;
configuring a simulator in an initial configuration based on the initial configuration data set;
running the simulator starting in the initial configuration and simulating actions and/or conditions to obtain a simulated end configuration for the livestock area, with the simulation including simulation of a first damaging natural force; and
performing artificial intelligence analysis on the simulated end configuration to obtain a first recommendation for improving the agricultural crop area.

8. The CIM of claim 7 further comprising:
re-running the simulator with the re-running of the simulation including performance of the first recommendation to confirm that the first recommendation is likely to work successfully.

9. The CIM of claim 7 further comprising:
sending the first recommendation to a device of a farmer who raises livestock in the livestock area.

10. The CIM of claim 9 further comprising:
implementing the first recommendation in the livestock area.

11. The CIM of claim 7 wherein the livestock area includes at least one of the following kinds of livestock: insects, birds, mammals, reptiles and amphibians.

12. The CIM of claim 7 wherein the first damaging natural force is of one of the following types: fire, flood, earthquake, tsunami, solar radiation, other radiation from natural sources, ice, snow, insects, worms, wild animals, magnetic forces, pollen, natural chemicals and tidal forces.

13. A computer-implemented method (CIM) comprising:
receiving initial configuration data set for a forestry area, with the initial configuration data set including information on location size and color(s) of trees existing in the forestry area;
configuring a simulator in an initial configuration based on the initial configuration data set;
running the simulator starting in the initial configuration and simulating actions and/or conditions to obtain a simulated end configuration for the forestry area, with the simulation including simulation of a first damaging natural force; and
performing artificial intelligence analysis on the simulated end configuration to obtain a first recommendation for improving the forestry area.

14. The CIM of claim 13 further comprising:
re-running the simulator with the re-running of the simulation including performance of the first recommendation to confirm that the first recommendation is likely to work successfully.

15. The CIM of claim 13 further comprising:
sending the first recommendation to a device of a forester who manipulates the forestry area in various ways.

16. The CIM of claim 15 further comprising:
implementing the first recommendation in the forestry area.

17. The CIM of claim 13 wherein the forestry area is one of the following: park/preservation forest or lumber producing forest.

18. The CIM of claim 13 wherein the first damaging natural force is of one of the following types: fire, flood, earthquake, tsunami, solar radiation, other radiation from natural sources, ice, snow, insects, worms, wild animals, magnetic forces, pollen, natural chemicals and tidal forces.
